(19) United States
(12) Patent Application Publication
(10) Pub. No.: US 2023/0246106 A1
(43) Pub. Date: Aug. 3, 2023

(54) ISOLATION OF SEMICONDUCTOR DEVICE

(71) Applicant: TEXAS INSTRUMENTS INCORPORATED, Dallas, TX (US)

(72) Inventor: Ming-Yeh Chuang, McKinney, TX (US)

(21) Appl. No.: 17/588,930

(22) Filed: Jan. 31, 2022

(51) Int. Cl. H01L 29/78; H01L 29/66; H01L 29/06; H01L 21/761

(52) U.S. Cl. CPC H01L 29/7816; H01L 29/66681; H01L 29/0615; H01L 21/761

(57) ABSTRACT

The present disclosure generally relates to isolation of a semiconductor device formed in a semiconductor substrate. In an example, a semiconductor device includes a drift well, a drain region, a first dopant isolation region, and a second dopant isolation region. The drift well, drain region, first dopant isolation region, and second dopant isolation region are disposed in a semiconductor substrate. The drift well, drain region, and second dopant isolation region are doped with a first dopant conductivity type. The first dopant isolation region is doped with a second dopant conductivity type opposite from the first dopant conductivity type. The drain region is disposed within the drift well. The first dopant isolation region circumscribes the drain region. The first dopant isolation region is an electrically floating node. The second dopant isolation region circumscribes the first dopant isolation region.

### BACKGROUND

Laterally-diffused metal-oxide-semiconductor (LDMOS) transistors are a type of double-diffused metal-oxide-semiconductor field effect transistor (MOSFET). LDMOS transistors are capable of being implemented in high voltage and/or high power applications. However, continued scaling of semiconductor device sizes to smaller and smaller dimensions has raised challenges in LDMOS transistors.

### SUMMARY

This Summary is provided to introduce a brief selection of disclosed concepts in a simplified form that are further described below in the Detailed Description including the drawings provided. Various disclosed devices and methods may be beneficially applied to transistors and integrated circuits that include dual junction isolation structures, e.g., back-to-back diodes. While such embodiments may be expected to reduce the space needed to ensure breakdown-free operation of such isolation structures, no particular result is a requirement unless explicitly recited in a particular claim.

An example described herein is a semiconductor device. The semiconductor device includes a drift well, a drain region, a first dopant isolation region, and a second dopant isolation region. The drift well is disposed in a semiconductor substrate. The drift well is doped with a first dopant conductivity type. The drain region is disposed in the semiconductor substrate. The drain region is disposed within the drift well. The drain region is doped with the first dopant conductivity type. The first dopant isolation region is disposed in the semiconductor substrate and circumscribes the drain region. The first dopant isolation region is doped with a second dopant conductivity type opposite from the first dopant conductivity type. The first dopant isolation region is an electrically floating node. The second dopant isolation region is disposed in the semiconductor substrate and circumscribes the first dopant isolation region. The second dopant isolation region is doped with the first dopant conductivity type.

Another example is a method of forming a semiconductor device. The method includes forming a drift well in a semiconductor substrate, forming a drain region in the drift well, forming a first dopant isolation region in the semiconductor substrate, forming a second dopant isolation region in the semiconductor substrate, and forming a dielectric layer on or over the semiconductor substrate. The drift well is doped with a first dopant conductivity type. The drain region is doped with the first dopant conductivity type. A concentration of a dopant of the first dopant conductivity type in the drain region is greater than a concentration of a dopant of the first dopant conductivity type in the drift well. The first dopant isolation region laterally surrounds the drain region and is doped with a second dopant conductivity type opposite from the first dopant conductivity type. The first dopant isolation region laterally surrounds the drain region and is disposed laterally between the drift well and the second dopant isolation region. The second dopant isolation region is doped with the first dopant conductivity type. The first dopant isolation region is configured to be unconnected to any constant or varying voltage source or ground reference during operation of the semiconductor device.

A further example is an integrated circuit. The integrated circuit includes an n-doped drift well, an n-doped drain region, a p-doped well region, and an n-doped isolation region. The n-doped drift well is disposed in a semiconductor substrate. The n-doped drain region is disposed in the n-doped drift well. A concentration of an n-type dopant in the n-doped drain region is greater than a concentration of an n-type dopant in the n-doped drift well. The p-doped well region is disposed in the semiconductor substrate and laterally surrounds the n-doped drain region. The p-doped well region is an electrically floating node. The n-doped isolation region is disposed in the semiconductor substrate. The p-doped well region is disposed laterally between the n-doped drift well and the n-doped isolation region.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a cross-sectional view of a semiconductor device structure according to some examples.

FIG. 2 is a layout view of the semiconductor device structure of FIG. 1 according to some examples.

FIGS. 3 through 17 are cross-sectional views at various stages of semiconductor processing to form the semiconductor device structure of FIG. 1 according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations. In the following discussion, doping levels may be described in quantitative and/or qualitative terms, wherein a doping level less than 1×10¹⁶ cm⁻³ is lightly doped, a doping level between 1×10¹⁶ cm⁻³ and 1×10¹⁸ cm³ is moderately doped, a doping level between 1×10¹⁸ cm⁻³ and 1×10²⁰ cm³ is heavily doped, and a doping level above 1×10²⁰ cm⁻³ is very heavily doped. A doping level at the boundaries of these ranges may be referred to qualitatively by either term referring to the higher or lower range.

The present disclosure relates generally, but not exclusively, to isolation of a transistor formed in a semiconductor substrate. In some examples, a dopant isolation region is incorporated into a semiconductor device structure that is or includes a laterally-diffused metal-oxide-semiconductor (LDMOS) transistor. The LDMOS transistor can be a sense field effect transistor (FET), in some examples. The dopant isolation region includes one or more doped regions and/or wells disposed in a semiconductor substrate. The dopant isolation region is an electrically floating node, as described further below.

In an LDMOS transistor, and more specifically, an n-channel LDMOS transistor, the dopant isolation region is disposed in a semiconductor substrate and is doped with a first dopant conductivity type (e.g., p-type). The dopant isolation region can be disposed laterally between a drift well and a counter-dopant isolation region, both of which are disposed in the semiconductor substrate and doped with a second dopant conductivity type (e.g., n-type) opposite from the first dopant conductivity type. A drain region doped with the second dopant conductivity type is disposed in the drift well. Hence, back-to-back diodes can be formed by the drain region and/or drift well, the dopant isolation region, and the counter-dopant isolation region. The dopant isolation region is an electrically floating node and is not electrically shorted (e.g., by metal contact(s) and/or metal lines) to another node of the LDMOS transistor, such as a source region of the LDMOS transistor. By having the dopant isolation region be an electrically floating node, a dimension between the drain region and the dopant isolation region can be reduced to be less than a distance at which breakdown would occur if the dopant isolation region was electrically shorted to the source region. Similarly, by having the dopant isolation region be an electrically floating node, a dimension between the dopant isolation region and the counter-dopant isolation region can be reduced to be less than a distance at which breakdown would occur if the dopant isolation region was electrically shorted to the source region. Accordingly, some examples can achieve a reduced footprint. Other benefits and advantages can be achieved.

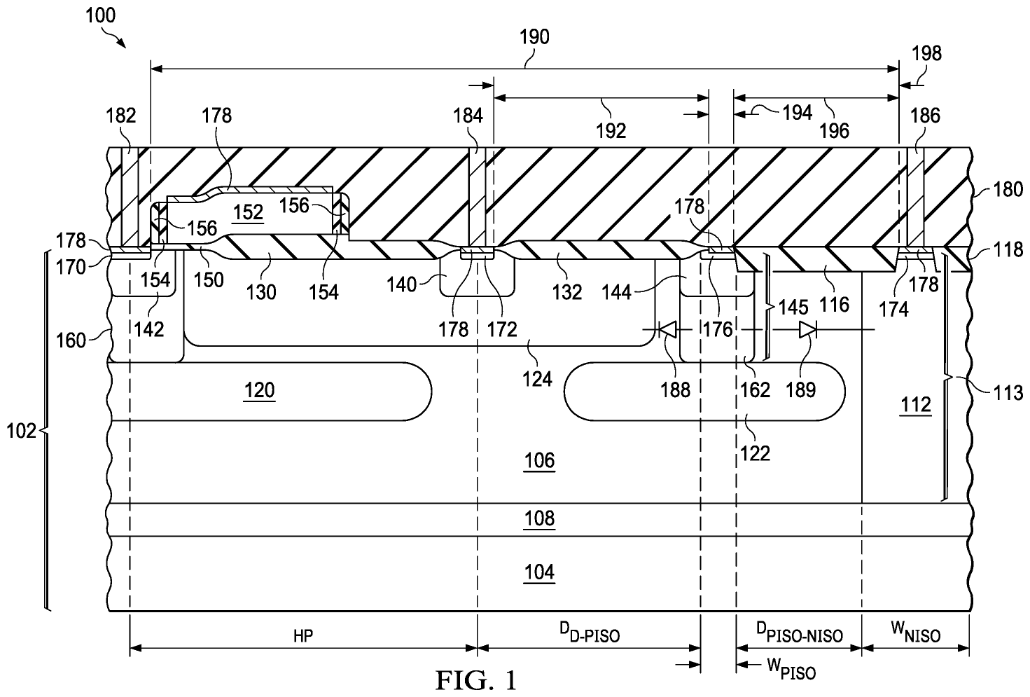

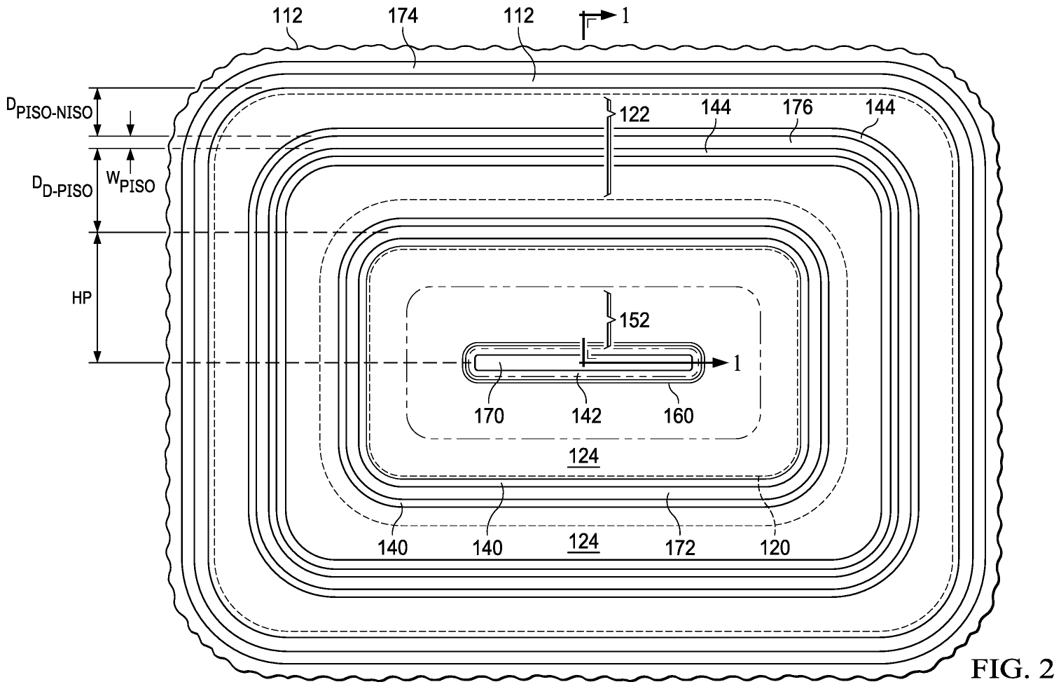

FIG. 1 is a cross-sectional view of a semiconductor device 100 according to some examples. FIG. 2 is a layout view of components of the semiconductor device 100 of FIG. 1 according to some examples. FIG. 2 shows cross-section 1-1 that is illustrated in FIG. 1.

The semiconductor device 100, in this example, is or includes an LDMOS transistor, which is in a colloquial lateral “racetrack” configuration as shown in FIG. 2. The semiconductor device 100 may be a single device on a semiconductor die, or may be a component of an integrated circuit that includes other electronic devices, interconnections, and connection terminals. The LDMOS transistor of the semiconductor device 100 of FIGS. 1 and 2 is described below as an n-channel LDMOS transistor. In other examples, the LDMOS transistor can be a p-channel LDMOS transistor. Further, the LDMOS transistor is a sense FET, and in other examples, the LDMOS transistor may not be a sense FET. Some aspects of the semiconductor device 100 are shown generically so as to not obscure aspects described herein. Additionally, an LDMOS transistor can be in a number of different configurations, and the LDMOS transistor shown in FIGS. 1 and 2 is merely an example to illustrate various aspects described herein.

The semiconductor device 100 includes a semiconductor substrate 102. The semiconductor substrate 102, in the illustrated example, includes a semiconductor support (or handle) substrate 104 (or handle wafer) and an epitaxial layer 106. The semiconductor support substrate 104 can be a bulk semiconductor substrate, a semiconductor-on-insulator (SOI) substrate, or any other appropriate substrate. The epitaxial layer 106 is epitaxially grown on or over the semiconductor support substrate 104. The epitaxial layer 106 can be or include silicon (Si), silicon germanium (SiGe), gallium arsenide (GaAs), gallium nitride (GaN), the like, or a combination thereof. In some examples, the semiconductor support substrate 104 is or includes a silicon substrate (which may be singulated from a bulk silicon wafer at the conclusion of semiconductor processing), and the epitaxial layer 106 is or includes a layer of silicon. In some examples, the epitaxial layer 106 can be omitted, and a semiconductor material of the semiconductor substrate 102 (e.g., in or on which devices are formed) can be or include silicon (Si), silicon germanium (SiGe), gallium arsenide (GaAs), the like, or a combination thereof. The semiconductor substrate 102 has a top major surface in and/or on which devices (e.g., transistors) are generally disposed and formed.

A deep buried layer 108 is disposed in the semiconductor support substrate 104. The deep buried layer 108 extends from an interface between the semiconductor support substrate 104 and the epitaxial layer 106 to a depth in the semiconductor support substrate 104. The deep buried layer 108 includes a portion of the semiconductor support substrate 104 doped by a dopant. In the n-channel LDMOS transistor, the deep buried layer 108 can be an n-type layer doped with an n-type dopant (e.g., phosphorous and/or arsenic) at a concentration in a range from about 1×10¹⁷ cm⁻³ to about 8×10¹⁸ cm⁻³, e.g., moderately to heavily doped.

The epitaxial layer 106 is doped with a dopant. The dopant with which the epitaxial layer 106 is doped has a conductivity type that is counter (e.g., opposite from) the conductivity type of the dopant with which the deep buried layer 108 is doped. In the n-channel LDMOS transistor, the epitaxial layer 106 can be p-doped in situ with a p-type dopant (e.g., boron) at a concentration in a range from about 1×10¹⁴ cm⁻³ to about 5×10¹⁵ cm⁻³, e.g., lightly doped.

As mentioned, in some examples, the epitaxial layer 106 may be omitted. In such examples, the deep buried layer 108 may be implanted at a depth in the semiconductor substrate 102, and a well can be implanted in the semiconductor substrate 102 extending from a top major surface of the semiconductor substrate 102 to a depth to or above the deep buried layer 108. The well can be counter-doped from the deep buried layer 108 like described with respect to the epitaxial layer 106.

A deep well 112 is disposed in the semiconductor substrate 102 (e.g., in the epitaxial layer 106, as illustrated). The deep well 112 extends from proximate the top major surface of the semiconductor substrate 102 to the deep buried layer 108. The deep well 112 is doped with a dopant. The dopant with which the deep well 112 is doped has a conductivity type that is the same as the conductivity type of the dopant with which the deep buried layer 108 is doped and that is counter the conductivity type of the dopant with which the epitaxial layer 106 is doped. In the n-channel LDMOS transistor, the deep well 112 can be an n-well doped with an n-type dopant at a concentration in a range from about 1×10¹⁷ cm⁻³ to about 2×10²⁰ cm⁻³, e.g., moderately to heavily doped.

First dielectric isolation regions 116, 118 are disposed at the top major surface of the semiconductor substrate 102 and extend into the semiconductor substrate 102 (e.g., in the epitaxial layer 106, as illustrated). The first dielectric isolation regions 116, 118 can be or include any appropriate dielectric or isolation material. In some examples, the first dielectric isolation regions 116, 118 are shallow trench isolations (STIs), and in some examples, the first dielectric isolation regions 116, 118 can be other dielectric isolation regions, such as field oxide regions. The first dielectric isolation regions 116, 118 are disposed at least partially laterally within the deep well 112 and extend laterally away from the deep well 112.

Mid-buried layers 120, 122 are disposed in the semiconductor substrate 102 (e.g., in the epitaxial layer 106, as illustrated). The mid-buried layers 120, 122 are disposed at a generally same depth in the semiconductor substrate 102 (e.g., in the epitaxial layer 106, as illustrated) and some distance above the deep buried layer 108. The mid-buried layers 120, 122 are doped with a dopant. The dopant with which the mid-buried layers 120, 122 are doped has a conductivity type that is the same as the conductivity type of the dopant with which the epitaxial layer 106 is doped and that is counter the conductivity type of the dopants with which the deep buried layer 108 and deep well 112 are doped. A concentration of the dopant in the mid-buried layers 120, 122 is greater than (e.g., an order of magnitude or more greater than) a concentration of the dopant in the epitaxial layer 106. In the n-channel LDMOS transistor, the mid-buried layers 120, 122 can be a p-layer doped with a p-type dopant at a concentration in a range from about 1×10¹⁶ cm⁻³ to about 1×10¹⁸ cm⁻³, e.g., moderately doped.

In the racetrack configuration, as illustrated in FIG. 2, the deep well 112 laterally encircles the mid-buried layer 122, and the mid-buried layer 122 laterally encircles the mid-buried layer 120. In such configuration and other configurations, the mid-buried layer 122 can be disposed laterally between the mid-buried layer 120 and the deep well 112. The mid-buried layer 122 is disposed laterally a distance from the deep well 112, and the mid-buried layer 120 is disposed laterally a distance from the mid-buried layer 122. In some examples, the mid-buried layers 120, 122 may be a single, continuous mid-buried layer.

A drift well 124 is disposed in the semiconductor substrate 102 (e.g., in the epitaxial layer 106, as illustrated). The drift well 124 extends from the top major surface of the semiconductor substrate 102 into a depth in the semiconductor substrate 102. The drift well 124 is at least partially over the mid-buried layer 120 and at least partially over the mid-buried layer 122. The depth to which the drift well 124 extends is above the mid-buried layers 120, 122. The drift well 124 is disposed laterally surrounded by and interior to the deep well 112. The drift well 124 is doped with a dopant. The dopant with which the drift well 124 is doped has a conductivity type that is the same as the conductivity type of the dopant with which the deep buried layer 108 and deep well 112 are doped and that is counter the conductivity type of the dopants with which the epitaxial layer 106 and mid-buried layers 120, 122 are doped. In the n-channel LDMOS transistor, the drift well 124 can be an n-well doped with an n-type dopant at a concentration in a range from about 1×10¹⁶ cm⁻³ to about 5×10¹⁷ cm⁻³, e.g., moderately doped.

Second dielectric isolation regions 130, 132 are disposed on or over the semiconductor substrate 102 (e.g., on or over the epitaxial layer 106, as illustrated). The second dielectric isolation region 130 is disposed at the top major surface of the semiconductor substrate 102 laterally within the drift well 124. The second dielectric isolation region 130 is disposed overlying and laterally within the drift well 124. The second dielectric isolation region 132 is disposed at least partially overlying and laterally within the drift well 124. The second dielectric isolation region 132 extends laterally outside of the drift well 124 in a direction laterally towards the deep well 112. In some examples, the second dielectric isolation regions 130, 132 are field oxide regions, such as local oxidation of semiconductor (LOCOS) regions, and in other examples, the second dielectric isolation regions 130, 132 can be other dielectric isolation regions, such as STIs.

A first shallow well 140 is disposed in the semiconductor substrate 102 (e.g., in the epitaxial layer 106, as illustrated). The first shallow well 140 is disposed in the drift well 124 in the semiconductor substrate 102. The first shallow well 140 extends from the top major surface of the semiconductor substrate 102 to a depth in the drift well 124. The first shallow well 140 is disposed laterally between the second dielectric isolation regions 130, 132. The dopant with which the first shallow well 140 is doped has a conductivity type that is the same as the conductivity type of the dopant with which the drift well 124 is doped. A concentration of the dopant in the first shallow well 140 is greater than (e.g., by an order of magnitude or more) a concentration of the dopant in the drift well 124. In the n-channel LDMOS transistor, the first shallow well 140 can be an n-well doped with an n-type dopant (e.g., phosphorus or arsenic) at a concentration in a range from about 5×10¹⁷ cm⁻³ to about 1×10¹⁹ cm⁻³, e.g., moderately to heavily doped.

Second shallow wells 142, 144 are disposed in the semiconductor substrate 102 (e.g., in the epitaxial layer 106, as illustrated). The second shallow wells 142, 144 extend from the top major surface of the semiconductor substrate 102 to a depth in the semiconductor substrate 102. The second shallow well 144 is disposed laterally between the second dielectric isolation region 132 and the first dielectric isolation region 116. The drift well 124 is disposed laterally between the second shallow wells 142, 144. In the racetrack configuration, as illustrated in FIG. 2, the second shallow well 144 laterally encircles the drift well 124, and the drift well 124 laterally encircles the second shallow well 142. The second shallow well 144 is disposed laterally a distance from the drift well 124. The dopant with which the second shallow wells 142, 144 are doped has a conductivity type that is the same as the conductivity type of the dopant with which the mid-buried layers 120, 122 and epitaxial layer 106 are doped and that is counter the conductivity type of the dopant with which the drift well 124 is doped. In the n-channel LDMOS transistor, the second shallow wells 142, 144 can each be a p-well doped with a p-type dopant at a concentration in a range from about 5×10¹⁷ cm⁻³ to about 5×10¹⁸ cm⁻³, e.g., moderately to heavily doped.

A dielectric layer 150 extends laterally from the second dielectric isolation region 130, and a gate electrode 152 is disposed on or over the second dielectric isolation region 130 and the dielectric layer 150. The dielectric layer 150 may be a gate dielectric layer. The dielectric layer 150 extends laterally from the second dielectric isolation region 130 to overlying at least partially the second shallow well 142. The dielectric layer 150 can be or include any appropriate dielectric material, such as an oxide, nitride, the like, or a combination thereof. The gate electrode 152 can be or include any appropriate conductive material, such as polysilicon (e.g., doped polysilicon), metal (e.g., tungsten (W), aluminum (Al), titanium (Ti), tantalum (Ta), or the like), the like, or a combination thereof.

Oxide layers 154 are disposed along sidewall surfaces of the gate electrode 152, and spacers 156 are disposed on the oxide layers 154 disposed along sidewall surfaces of the gate electrode 152. The spacers 156 can be or include any appropriate dielectric material, such as an oxide, a nitride, the like, or a combination thereof.

A double diffusion well (Dwell) 160 and a mid-depth well 162 are disposed in the semiconductor substrate 102 (e.g., in the epitaxial layer 106, as illustrated). The Dwell 160 extends from the top major surface of the semiconductor substrate 102 to a depth in the semiconductor substrate 102 to the mid-buried layer 120. The second shallow well 142 is disposed in the Dwell 160 and extends to a depth in the Dwell 160. The Dwell 160 is disposed at least partially underlying the dielectric layer 150 that extends from the second dielectric isolation region 130.

The mid-depth well 162 extends from the top major surface of the semiconductor substrate 102 to a depth in the semiconductor substrate 102 to the mid-buried layer 122. The second shallow well 144 is disposed in the mid-depth well 162 and extends to a depth in the Dwell 160. The mid-depth well 162 is disposed laterally between the second dielectric isolation region 132 and the first dielectric isolation region 116 and is generally laterally co-extensive with the second shallow well 144.

In the racetrack configuration, as illustrated in FIG. 2, the drift well 124 laterally encircles the Dwell 160 and the second shallow well 142, and the mid-depth well 162 and the second shallow well 144 laterally encircle the drift well 124. In such configuration and other configurations, the drift well 124 can be disposed laterally between (i) the Dwell 160 and the second shallow well 142 and (ii) the mid-depth well 162 and the second shallow well 144.

The Dwell 160 and the mid-depth well 162 are doped with a dopant having a same conductivity type as the dopant with which the second shallow wells 142, 144 and mid-buried layers 120, 122 are doped. A concentration of the dopant in the Dwell 160 is greater than (e.g., by an order of magnitude or more) a concentration of the dopant in the mid-buried layer 120. A concentration of the dopant in the mid-depth well 162 is greater than (e.g., by an order of magnitude or more) a concentration of the dopant in the mid-buried layer 122. In the n-channel LDMOS transistor, the Dwell 160 and the mid-depth well 162 can each be p-doped with a p-type dopant at a concentration in a range from about 1×10¹⁸ cm⁻³ to about 1×10¹⁹ cm⁻³, e.g., heavily doped.

A source region 170 is disposed in the second shallow well 142 extending from the top major surface of the semiconductor substrate 102 to a depth in the second shallow well 142 in the semiconductor substrate 102. The source region 170 is doped with a dopant having an opposite conductivity type as the dopant with which the second shallow well 142 is doped. In the n-channel LDMOS transistor, the source region 170 can be n-doped with an n-type dopant at a concentration in a range from about 1×10²⁰ cm⁻³ to about 3×10²¹ cm⁻³, e.g., very heavily doped.

A drain region 172 is disposed in the first shallow well 140 extending from the top major surface of the semiconductor substrate 102 to a depth in the first shallow well 140 in the semiconductor substrate 102. The drain region 172 is disposed laterally between the second dielectric isolation regions 130, 132. The gate electrode 152 is disposed laterally between the source region 170 and the drain region 172. The drain region 172 is doped with a dopant having a conductivity type that is the same as the dopants with which the source region 170 and the first shallow well 140 are doped. A concentration of the dopant of the drain region 172 can be greater than (e.g., an order of magnitude or more) the concentration of the dopant in the first shallow well 140. In the n-channel LDMOS transistor, the drain region 172 can be n-doped with an n-type dopant at a concentration in a range from about 1×10²⁰ cm⁻³ to about 3×10²¹ cm⁻³, e.g., very heavily doped.

A counter-isolation surface region 174 is disposed in the deep well 112 extending from the top major surface of the semiconductor substrate 102 to a depth in the deep well 112 in the semiconductor substrate 102. The counter-isolation surface region 174 is disposed laterally between the first dielectric isolation regions 116, 118. The counter-isolation surface region 174 is doped with a dopant having a conductivity type that is the same as the dopant with which the deep well 112 is doped. A concentration of the dopant of the counter-isolation surface region 174 can be greater than (e.g., an order of magnitude or more) the concentration of the dopant in the deep well 112. In the n-channel LDMOS transistor, the counter-isolation surface region 174 can be n-doped with an n-type dopant at a concentration in a range from about 1×10²⁰ cm⁻³ to about 3×10²¹ cm⁻³, e.g., very heavily doped.

An isolation surface region 176 is disposed in the second shallow well 144 extending from the top major surface of the semiconductor substrate 102 to a depth in the second shallow well 144 in the semiconductor substrate 102. The isolation surface region 176 is disposed laterally between the second dielectric isolation region 132 and the first dielectric isolation region 116. The isolation surface region 176 is doped with a dopant having a conductivity type that is the same as the dopant with which the second shallow well 144 is doped. A concentration of the dopant of the isolation surface region 176 can be greater than (e.g., an order of magnitude or more) the concentration of the dopant in the second shallow well 144. In the n-channel LDMOS transistor, the isolation surface region 176 can be p-doped with a p-type dopant at a concentration in a range from about 1×10²⁰ cm⁻³ to about 1×10²¹ cm⁻³, e.g., very heavily doped. In some examples, the isolation surface region 176 may be omitted.

FIG. 2 shows, in a layout view of the racetrack configuration, concentric rounded polygon shapes and/or regular polygon shapes of the deep well 112, mid-buried layers 120, 122, drift well 124, Dwell 160, mid-depth well 162, first shallow well 140, second shallow wells 142, 144, source region 170, drain region 172, isolation surface region 176, and counter-isolation surface region 174. FIG. 2 shows which buried layer, well, or region is laterally surrounded by and interior to another well or region, and which buried layer, well, or region is laterally outward of and surrounding another well or region. Similarly, FIG. 2 shows in phantom a rounded polygon shape and/or regular polygon shape of the gate electrode 152 in relation to the buried layers, wells, and/or regions. Although not specifically illustrated, the second dielectric isolation region 130 with connecting dielectric layer 150 tracks the rounded polygon shape of the gate electrode 152.

In some examples, the first dielectric isolation regions 116, 118 and second dielectric isolation regions 130, 132 can be a same type of dielectric isolation region, different types of dielectric isolation regions, or any combination thereof. In some examples, the first dielectric isolation regions 116, 118 and second dielectric isolation regions 130, 132 can be field oxide regions, (e.g., LOCOS regions). In some examples, the first dielectric isolation regions 116, 118 and second dielectric isolation regions 130, 132 can be STIs. Additionally, the first dielectric isolation region 116 and the second dielectric isolation region 132, in some examples, may be a continuous dielectric isolation region extending at the top major surface of the semiconductor substrate 102 from the drain region 172 to the counter-isolation surface region 174, such as when the isolation surface region 176 is omitted.

Referring back to FIG. 1, semiconductor-metal compound regions 178 are disposed on respective regions at the top major surface of the semiconductor substrate 102 and on a top surface of the gate electrode 152. Such semiconductor-metal compound regions are sometimes referred to a metal-silicide regions (for a silicon substrate), or simply silicide regions. A semiconductor-metal compound region 178 is disposed on the source region 170 at the top major surface of the semiconductor substrate 102. A semiconductor-metal compound region 178 is disposed on the drain region 172 at the top major surface of the semiconductor substrate 102. A semiconductor-metal compound region 178 is disposed on the counter-isolation surface region 174 at the top major surface of the semiconductor substrate 102. A semiconductor-metal compound region 178 is disposed on the isolation surface region 176 at the top major surface of the semiconductor substrate 102. In some examples, a semiconductor-metal compound region 178 disposed on the isolation surface region 176 may be omitted, such as when the isolation surface region 176 is omitted. A semiconductor-metal compound region 178 is disposed on the top surface of the gate electrode 152. In some examples, the semiconductor-metal compound regions 178 can be a silicide, such as when the epitaxial layer 106 and gate electrode 152 is or includes silicon (Si). A metal of the semiconductor-metal compound regions 178 can be or include nickel (Ni), tungsten (W), molybdenum (Mo), titanium (Ti), magnesium (Mg), the like, or a combination thereof.

A dielectric layer 180 is disposed on or over the semiconductor substrate 102. Such a dielectric layer is sometimes referred to as a pre-metal dielectric layer. More specifically, the dielectric layer 180 is disposed on or over a portion of second dielectric isolation region 130 not underlying the gate electrode 152, the second dielectric isolation region 132, first dielectric isolation regions 116, 118, semiconductor-metal compound regions 178, and spacers 156. The dielectric layer 180 can include multiple dielectric layers. For example, the dielectric layer 180 can include an etch stop layer (e.g., silicon nitride (SiN) or the like) disposed conformally along surfaces of, e.g., the portion of second dielectric isolation region 130 not underlying the gate electrode 152, the second dielectric isolation region 132, the first dielectric isolation regions 116, 118, the semiconductor-metal compound regions 178, and the spacers 156, and can include an inter-layer dielectric (e.g., an oxide or the like) disposed on the etch stop layer.

One or more source contacts 182 are disposed through the dielectric layer 180 and contact the semiconductor-metal compound region 178 disposed on the source region 170. One or more drain contacts 184 are disposed through the dielectric layer 180 and contact the semiconductor-metal compound region 178 disposed on the drain region 172. One or more counter-isolation contacts 186 are disposed through the dielectric layer 180 and contact the semiconductor-metal compound region 178 disposed on the counter-isolation surface region 174. Each of the source contacts 182, drain contacts 184, and counter-isolation contacts 186 can include one or more barrier and/or adhesion layers (e.g., titanium nitride (TiN), tantalum nitride (TaN), the like, or a combination thereof) conformally in a respective opening through the dielectric layer 180, and can include a conductive fill material (e.g., a metal, such as tungsten (W), copper (Cu), a combination thereof, or the like). In the illustrated example, no contact is disposed contacting the isolation surface region 176 and/or the semiconductor-metal compound region 178 disposed on the isolation surface region 176. In other examples, a contact through the dielectric layer 180 may be disposed contacting the isolation surface region 176 and/or the semiconductor-metal compound region 178 disposed on the isolation surface region 176.

The semiconductor device 100 includes a dopant isolation region 145 disposed in the semiconductor substrate 102. The dopant isolation region 145 includes the mid-depth well 162 and the second shallow well 144. When included, the dopant isolation region 145 may include the isolation surface region 176 and/or the semiconductor-metal compound region 178 disposed on the isolation surface region 176. The dopant isolation region 145 may be a guard ring laterally encircling other components of the LDMOS transistor that are disposed in the semiconductor substrate 102, such as the drift well 124, drain region 172, Dwell 160, and source region 170. The dopant isolation region 145 may be referred to without implied limitation as a P-isolation region, or PISO region, consistent with examples for which the semiconductor device 100 includes an n-type LDMOS transistor. The dopant isolation region 145 may also be referred to herein as an “electrically floating node,” and has a floating voltage potential, meaning that the electrical potential of the dopant isolation region 145 is unconstrained by any direct conductive, e.g., metallic, connection to a constant or varying voltage source or ground reference. In the illustrated example, no contact is disposed contacting or electrically directly connected to a region or well in the dopant isolation region 145. If a contact is disposed contacting or electrically directly connected to, e.g., the semiconductor-metal compound region 178 disposed on the isolation surface region 176 in the illustrated example, the contact is not configured to and does not form a part of an electrical node on which an independent electrical voltage is applied. A voltage potential of the dopant isolation region 145 may be indirectly determined by potentials applied to other features of the semiconductor device 100, for example, potentials applied to the source region 170, drain region 172, and counter-dopant isolation region 113.

The semiconductor device 100 further includes a counter-dopant isolation region 113 disposed in the semiconductor substrate 102. The counter-dopant isolation region 113 may be referred to without implied limitation as an N-isolation region, or NISO region, consistent with examples for which the semiconductor device 100 includes an n-type LDMOS transistor. The counter-dopant isolation region 113 includes the deep well 112 and the counter-isolation surface region 174 in the illustrated example. The dopant isolation region 145 may be regarded as a first dopant isolation region, and the counter-dopant isolation region 113 may be regarded as a second dopant isolation region.

In the n-type LDMOS transistor in the semiconductor device 100 as described by the foregoing, the dopant isolation region 145 forms a p-n junction, and hence, a diode 188, with the drift well 124, first shallow well 140, and/or drain region 172, and forms a p-n junction, and hence, a diode 189, with the deep well 112 and/or counter-isolation surface region 174. The second shallow well 144 and mid-depth well 162 are doped with a p-type dopant, and one or both form respective anodes of the diodes 188, 189. The drift well 124, first shallow well 140, and drain region 172 are doped with an n-type dopant and individually or together form a cathode of the diode 188. The deep well 112 and counter-isolation surface region 174 are doped with an n-type dopant and individually or together form a cathode of the diode 189. The diodes 188, 189 form back-to-back junction diodes that may isolate the drain region 172 from the deep well 112 and that may reduce leakage current between the drain region 172 and the deep well 112.

A first dimension 190 is between a lateral edge of the source region 170 that is nearest to the counter-isolation surface region 174 and a lateral edge of the counter-isolation surface region 174 that is nearest to the source region 170. The respective lateral edges of the source region 170 and the counter-isolation surface region 174 are at the top major surface of the semiconductor substrate 102. The lateral edge of the source region 170 is defined by, in the illustrated example, the dielectric layer 150. The lateral edge of the counter-isolation surface region 174 is defined by, in the illustrated example, the first dielectric isolation region 116.

A second dimension 192 is between a lateral edge of the drain region 172 that is nearest to the dopant isolation region 145 and a lateral edge of the isolation surface region 176 of the dopant isolation region 145, in the illustrated example, that is nearest to the drain region 172. The respective lateral edges of the drain region 172 and the isolation surface region 176 are at the top major surface of the semiconductor substrate 102. The respective lateral edges of the drain region 172 and the isolation surface region 176 are defined by, in the illustrated example, opposing lateral edges of the second dielectric isolation region 132. The second dimension 192 corresponds to a lateral dimension of the second dielectric isolation region 132.

A third dimension 194 is a lateral width of the isolation surface region 176 of the dopant isolation region 145. The width of the isolation surface region 176 is at the top major surface of the semiconductor substrate 102. The second dielectric isolation region 132 defines, in the illustrated example, a lateral edge of the isolation surface region 176, and the first dielectric isolation region 116 defines an opposing lateral edge of the isolation surface region 176. The width of the isolation surface region 176 is between the opposing lateral edges of the isolation surface region 176.

A fourth dimension 196 is between a lateral edge of the isolation surface region 176, in the illustrated example, that is nearest to the counter-isolation surface region 174 and a lateral edge of the counter-isolation surface region 174 that is nearest to the dopant isolation region 145. The respective lateral edges of the isolation surface region 176 and the counter-isolation surface region 174 are at the top major surface of the semiconductor substrate 102. The respective lateral edges of the isolation surface region 176 and the counter-isolation surface region 174 are defined by, in the illustrated example, opposing lateral edges of the first dielectric isolation region 116. The fourth dimension 196 corresponds to a lateral dimension of the first dielectric isolation region 116.

A fifth dimension 198 is between a lateral edge of the drain region 172 that is nearest to the counter-isolation surface region 174 and a lateral edge of the counter-isolation surface region 174 that is nearest to the drain region 172. The lateral edges of the drain region 172 and the counter-isolation surface region 174 are as described above.

With the dopant isolation region 145 floating, various dimensions of the LDMOS transistor can be reduced compared to when the dopant isolation region 145 is electrically shorted with the source region 170 (e.g., through metal contact(s) and/or metal lines). When the dopant isolation region 145 is floating, the voltage potential of the dopant isolation region 145 can generally follow the voltage potential of the drain region 172 and/or counter-isolation surface region 174 in the sense FET. In such circumstances, respective magnitudes of the voltage differences (e.g., between the drain region 172 and the mid-depth well 162, and between the counter-isolation surface region 174 and the mid-depth well 162) for reverse bias of the p-n junctions of the diodes 188, 189 can remain small during operation. If the dopant isolation region 145 is electrically shorted to another node, such as electrically shorted with the source region 170, the voltage differences may vary significantly, since each node may be independently varied from another node. In such circumstances, respective magnitudes of the voltage differences for reverse bias of the p-n junctions can become large. Hence, according to some examples where the dopant isolation region 145 is floating, the likelihood of breakdown at those p-n junctions can be reduced. With the reduced likelihood of breakdown, dimensions between various regions and/or wells can be reduced, thereby reducing the footprint of an LDMOS transistor.

According to some examples, the second dimension 192 is less than a distance between the dopant isolation region 145 and the drain region 172 that would achieve breakdown of the p-n junction when the p-n junction is reversed biased by the voltage at which breakdown would occur between the source region 170 and the drain region 172. According to some examples, the fourth dimension 196 is less than a distance between the dopant isolation region 145 and the counter-isolation surface region 174 that would achieve breakdown of the p-n junction when the p-n junction is reversed biased by the voltage at which breakdown would occur between the source region 170 and the drain region 172. Equation (1) below shows a mathematical expression for a dimension D, which is the second dimension 192 or the fourth dimension 196, as applicable.

$$D < \sqrt{\frac{2 {V}_{BV} {k}_{S} {ε}_{0}}{q N}} , \qquad Equation ( 1 )$$

where V_{BV} is the breakdown voltage of the LDMOS transistor between the source region 170 and the drain region 172, kₛ is the dielectric constant of the semiconductor substrate 102 in which the p-n junction is disposed, ε₀ is the permittivity of a vacuum, q is charge, and N is the doping concentration of the p or n region that forms the p-n junction that has the lower concentration.

Further, according to some examples, the fifth dimension 198 is less than the sum of (i) a distance between the dopant isolation region 145 and the drain region 172 that would achieve breakdown of the p-n junction when the p-n junction is reversed biased by the voltage at which breakdown would occur between the source region 170 and the drain region 172, and (ii) a distance between the dopant isolation region 145 and the counter-isolation surface region 174 that would achieve breakdown of the p-n junction when the p-n junction is reversed biased by the voltage at which breakdown would occur between the source region 170 and the drain region 172.

In another perspective, the LDMOS transistor has a half-pitch, or HP, as shown in FIGS. 1 and 2. The HP is determined as the distance between the center of the source region 170 and the center of the drain region 172. A distance D_{D-PISO} is determined between the center of the drain region 172 and the side of the isolation surface region 176 nearest to the drain region 172. And a distance D_{PISO-NISO} is determined between the side of the isolation surface region 176 furthest from the drain region 172 and the deep well 112. The dopant isolation region 145 has a width W_{PISO}, and the counter-dopant isolation region 113 has a width W_{NISO}. A total “isolation size” of the semiconductor device 100 is D_{D-PISO+WPISO+DPISO-NISO+WNISO}.

The distance D_{D-PISO} and the distance D_{PISO-NISO} each have a minimum below which substrate breakdown may occur at a particular operating voltage. For instance, in some example implementations, a baseline LDMOS transistor is operated such that the source region and the PISO region are grounded, the NISO region has a potential of 85 volts, and the drain region has a maximum potential of about 83 volts. In such a configuration, the distances D_{D-PISO} and D_{PISO-NISO} may be a large amount relative to the HP to prevent substrate breakdown between the drain region and the PISO region and between the PISO region and the NISO region, thus consuming valuable space on the device die. In one specific baseline example, the HP may be 6.9 μm, the distance D_{D-PISO} may be 7.5 μm, and the distance D_{PISO-NISO} may be 10 μm. Thus, in some baseline implementations, the distance D_{D-PISO} may be about 110% of HP, and the distance D_{PISO-NISO} may be about 150% of HP. The total “isolation size” of the baseline device, D_{D-PISO+WPISO+DPISO-NISO+WNISO}, may be about 300% of HP.

In contrast to such baseline implementations, the LDMOS transistor of the semiconductor device 100 may space the drain region 172 and the counter-dopant isolation region 113 closer to the dopant isolation region 145 as a fraction of the HP. By leaving the isolation surface region 176 (or more generally, the dopant isolation region 145) unconnected to a potential source, the dopant isolation region 145 potential may be indirectly determined by the source voltage as coupled through the mid-buried layers 120, 122 and epitaxial layer 106. The dopant isolation region 145 is regarded as floating in spite of this indirect coupling to the source voltage via a semiconductive path. Using the baseline example voltages, without implied limitation, the dopant isolation region 145 potential may be about 55 volts when the source region 170 is grounded, the drain region 172 is 83 volts and the counter-isolation surface region 174 is held at 85 volts. Thus both the distances D_{D-PISO} and D_{PISO-NISO} may be reduced relative to the baseline example without risk of substrate breakdown. Under these conditions, the distances D_{D-PISO} and D_{PISO-NISO} may each be about 50% of HP, and the total isolation size may be as small as about 120% of HP.

Thus, in various examples of the semiconductor device 100, the isolation size may be no greater than 200% of HP, providing additional breakdown margin relative to 125% of HP. In some examples, the isolation size may be about 150% of HP, thus balancing breakdown margin against space reduction. Furthermore, the distance D_{D-PISO} may be as small as 50% of HP, or no greater than 75% of HP to provide additional breakdown margin. In one example provided without implied limitation, for a device with a half-pitch HP=5.4 μm, D_{D-PISO} may be about 3.0 μm, W_{PISO} may be about 0.7 μm, and D_{PISO-NISO} may be about 3.0 μm, for a total isolation size of about 6.7 μm. (In this context, “about” allows±5% excursion of values.) This example is contrasted with an otherwise equivalent baseline device for which the PISO region is shorted to the source, for which D_{D-PISO} would be about 4.5 μm and D_{PISO-NISO} would be about 6.5 μm, for a total isolation size of about 11.2 μm.

As noted above, the LDMOS transistor illustrated in FIGS. 1 and 2 is an example. Other LDMOS transistor structures incorporating aspects described herein may be implemented.

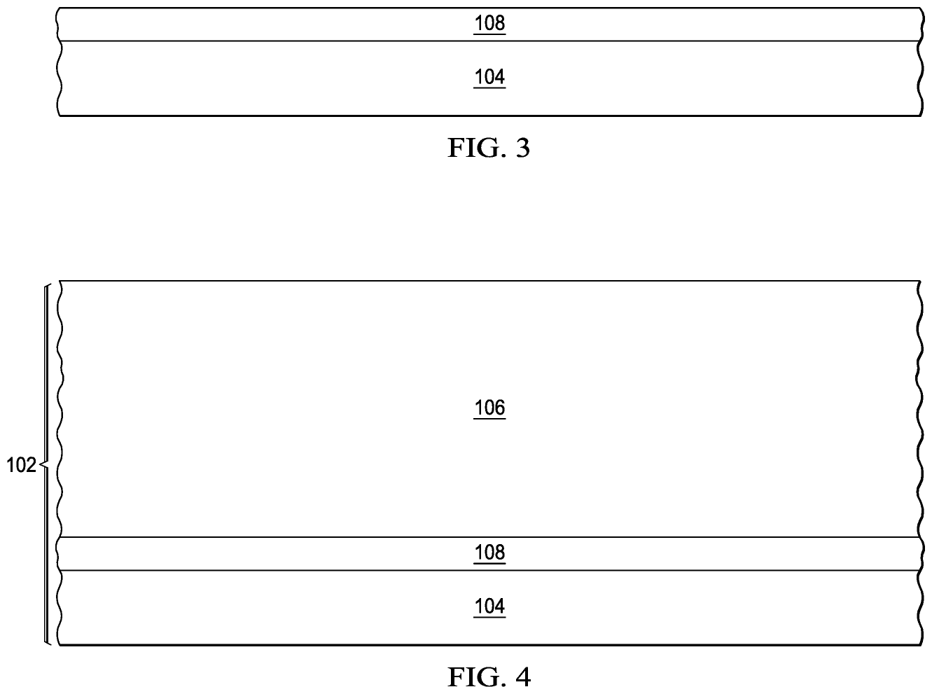

FIGS. 3 through 17 illustrate cross-sectional views of the semiconductor device 100 of FIG. 1 at various stages of manufacturing according to an example method. Referring to FIG. 3, a deep buried layer 108 is formed in a semiconductor support substrate 104. The deep buried layer 108 can be formed by implanting dopants into the semiconductor support substrate 104. In an example, the semiconductor support substrate 104 is a bulk silicon wafer. The dopant type and concentration of the deep buried layer 108 are as described above.

Referring to FIG. 4, an epitaxial layer 106 is formed on or over the semiconductor support substrate 104. The epitaxial layer 106 can be formed using an epitaxial growth by an appropriate epitaxial growth process, such as low pressure chemical vapor deposition (LPCVD) or the like. In an example, the epitaxial layer 106 is silicon. The epitaxial layer 106 is doped, such as by in situ during the epitaxial growth. The dopant type and concentration of the epitaxial layer 106 are as described above. In the illustrated example, the semiconductor support substrate 104 and the epitaxial layer 106 form a semiconductor substrate 102. In other examples, another semiconductor substrate can be used. For example, the semiconductor substrate 102 can be a bulk silicon wafer (e.g., without the epitaxial layer 106) with the deep buried layer 108 implanted to a deep depth in the semiconductor substrate 102.

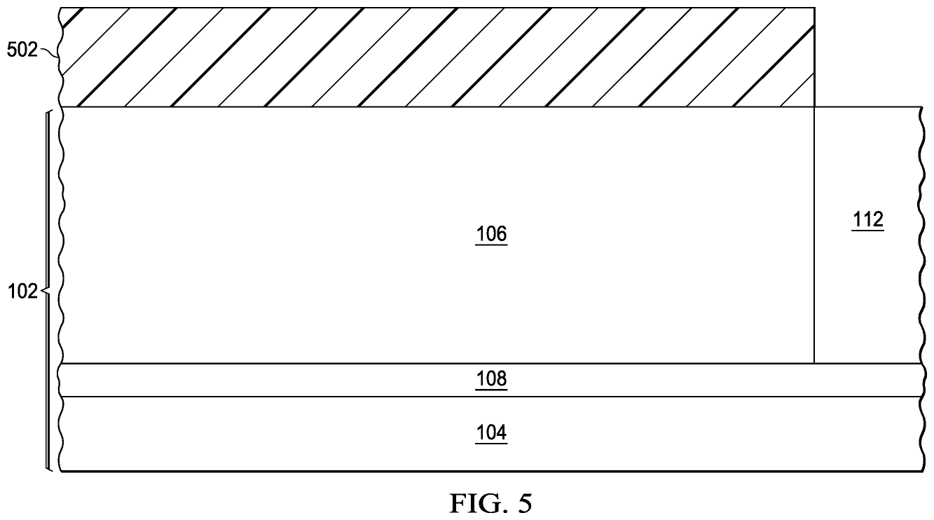

Referring to FIG. 5, a deep well 112 is formed in the semiconductor substrate 102. To form the deep well 112, a photoresist 502 is deposited (e.g., by spin-on) on or over the semiconductor substrate 102 and patterned using photolithography. The photoresist 502 is patterned to have an opening corresponding to an area where the deep well 112 is to be formed. With the patterned photoresist 502, an implant is performed to implant dopants into the semiconductor substrate 102 thereby forming the deep well 112. The dopant type and concentration of the deep well 112 are as described above. After the implant, the photoresist 502 is removed, such as by ashing.

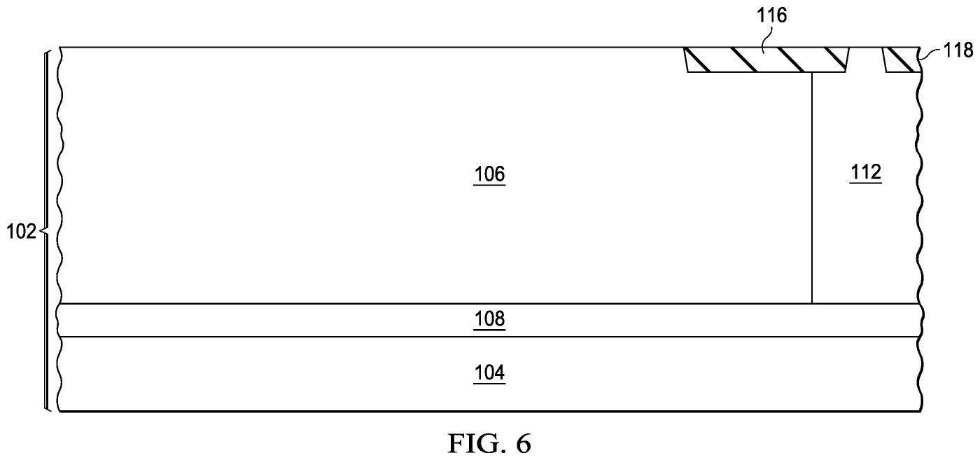

Referring to FIG. 6, first dielectric isolation regions 116, 118 are formed in the semiconductor substrate 102. In the illustrated example, the first dielectric isolation regions 116, 118 are STIs, and in other examples, the first dielectric isolation regions 116, 118 can be or include other dielectric isolation regions, such as field oxide regions. To form the illustrated first dielectric isolation regions 116, 118, a hardmask can be deposited on or over the semiconductor substrate 102 and patterned using appropriate photolithography and etching processes. Using the patterned hardmask, trenches are etched into the semiconductor substrate 102. A dielectric material is deposited in the trenches. For example, the dielectric material can be or include a nitride, an oxide, the like, or a combination thereof and may be deposited using atomic layer deposition (ALD), flowable chemical vapor deposition (FCVD), the like, or a combination thereof. Excess dielectric material and the hardmask can be removed, such as by using a chemical mechanical polish (CMP).

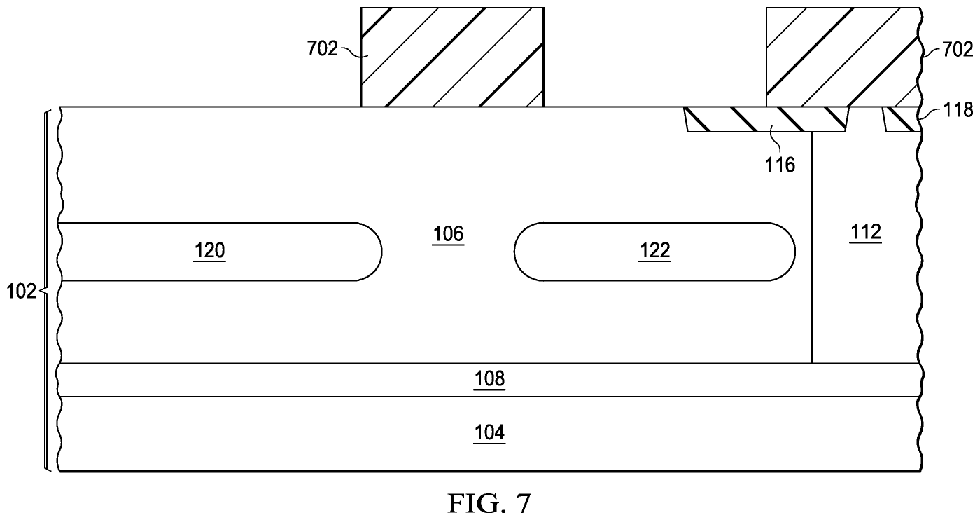

Referring to FIG. 7, mid-buried layers 120, 122 are formed in the semiconductor substrate 102. To form the mid-buried layers 120, 122, a photoresist 702 is deposited (e.g., by spin-on) on or over the semiconductor substrate 102 and patterned using photolithography. The photoresist 702 is patterned to have openings corresponding to areas where the mid-buried layers 120, 122 are to be formed. With the patterned photoresist 702, an implant is performed to implant dopants into the semiconductor substrate 102 thereby forming the mid-buried layers 120, 122. The dopant type and concentration of the mid-buried layers 120, 122 are as described above. After the implant, the photoresist 702 is removed, such as by ashing.

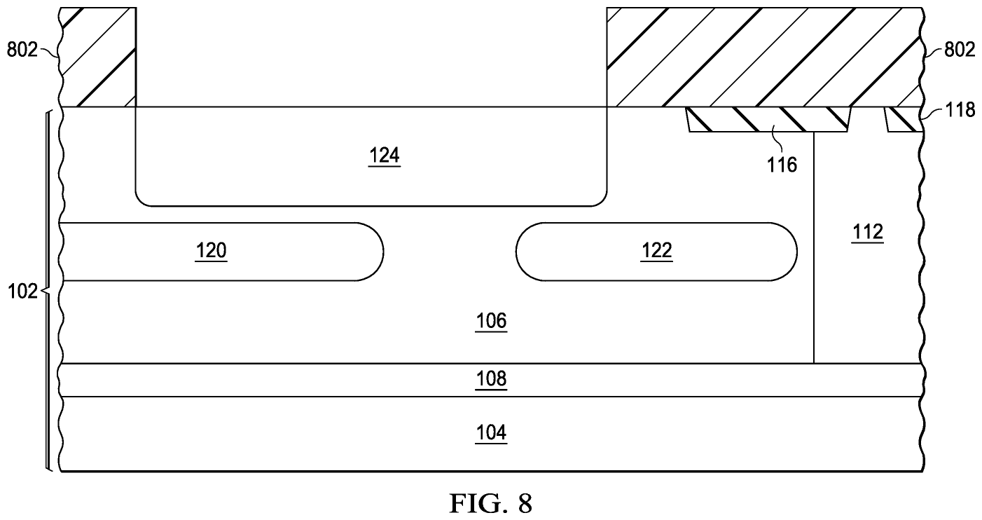

Referring to FIG. 8, a drift well 124 is formed in the semiconductor substrate 102. To form the drift well 124, a photoresist 802 is deposited (e.g., by spin-on) on or over the semiconductor substrate 102 and patterned using photolithography. The photoresist 802 is patterned to have an opening corresponding to an area where the drift well 124 is to be formed. With the patterned photoresist 802, an implant is performed to implant dopants into the semiconductor substrate 102 thereby forming the drift well 124. The dopant type and concentration of the drift well 124 are as described above. After the implant, the photoresist 802 is removed, such as by ashing. An anneal process may be performed after the implantation to activate the dopants of the deep well 112, the mid-buried layers 120, 122 and the drift well 124.

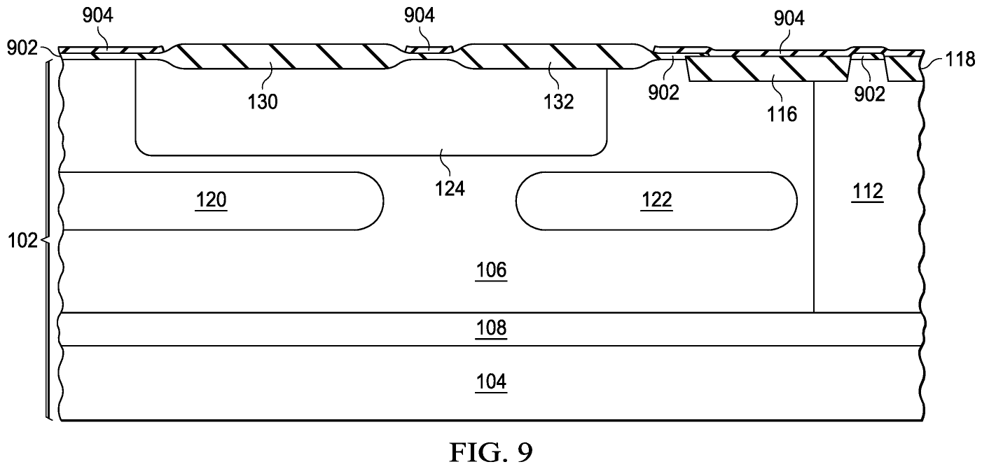

Referring to FIG. 9, second dielectric isolation regions 130, 132 are formed at the top major surface of the semiconductor substrate 102. To form the second dielectric isolation regions 130, 132, a pad oxide layer 902 is formed on the top major surface of the semiconductor substrate 102. In some examples, the pad oxide layer 902 is formed by performing an oxidation process to oxide the semiconductor material (e.g., silicon) at the top major surface of the semiconductor substrate 102. Hence, in such examples, the pad oxide layer 902 can be an oxide of the semiconductor material of the semiconductor substrate 102, such as silicon oxide. In other examples, the pad oxide layer 902 can be deposited on or over the semiconductor substrate 102 using an appropriate deposition process, such as, for example, chemical vapor deposition (CVD), ALD, or the like.

A mask layer 904 is formed on or over the pad oxide layer 902. In some examples, the mask layer 904 is a nitride, such as silicon nitride. The mask layer 904 can be deposited by any appropriate deposition process, such as CVD. The mask layer 904 is then patterned. The mask layer 904 is patterned to expose areas of the pad oxide layer 902 where field oxide regions will be formed. The mask layer 904 can be patterned using appropriate photolithography and etching processes.

An oxidation process is then performed to form the second dielectric isolation regions 130, 132. The oxidation process further oxidizes the semiconductor material (e.g., silicon) at the top major surface of the semiconductor substrate 102 to form the second dielectric isolation regions 130, 132. The oxidation process may be referred to as LOCOS. The formation of the first dielectric isolation regions 116, 118 and the second dielectric isolation regions 130, 132 can vary depending on the type of dielectric isolation regions that are implemented, as described above.

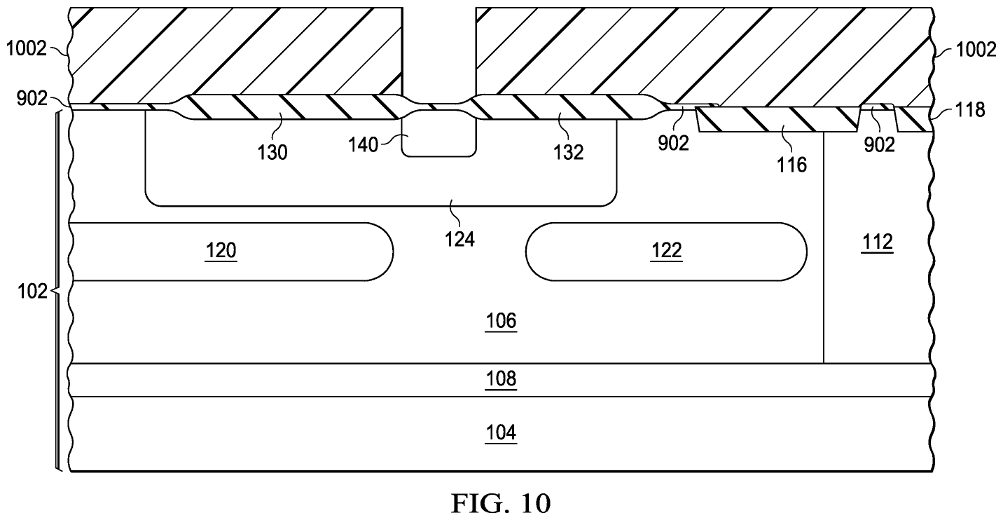

Referring to FIG. 10, the mask layer 904 is removed. For example, the mask layer 904 can be removed using an etch process. Then, a first shallow well 140 is formed in the semiconductor substrate 102. To form the first shallow well 140, a photoresist 1002 is deposited (e.g., by spin-on) on or over the semiconductor substrate 102 and patterned using photolithography. The photoresist 1002 is patterned to have an opening corresponding to an area where the first shallow well 140 is to be formed. With the patterned photoresist 1002, an implant is performed to implant dopants into the semiconductor substrate 102 thereby forming the first shallow well 140. The dopant type and concentration of the first shallow well 140 are as described above. After the implant, the photoresist 1002 is removed, such as by ashing.

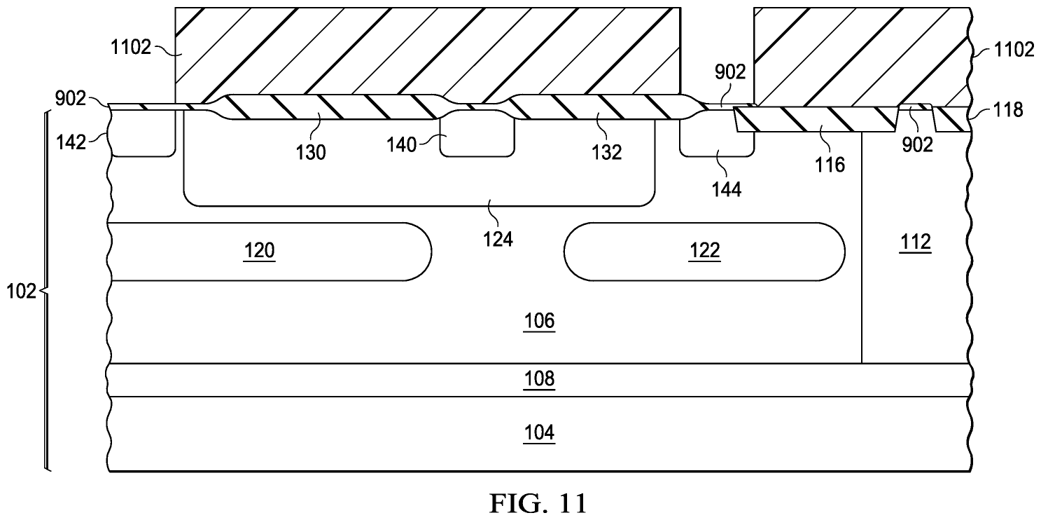

Referring to FIG. 11, second shallow wells 142, 144 are formed in the semiconductor substrate 102. To form the second shallow wells 142, 144, a photoresist 1102 is deposited (e.g., by spin-on) on or over the semiconductor substrate 102 and patterned using photolithography. The photoresist 1102 is patterned to have an opening corresponding to an area where the second shallow wells 142, 144 are to be formed. With the patterned photoresist 1102, an implant is performed to implant dopants into the semiconductor substrate 102 thereby forming the second shallow wells 142, 144. The dopant type and concentration of the second shallow wells 142, 144 are as described above. After the implant, the photoresist 1102 is removed, such as by ashing.

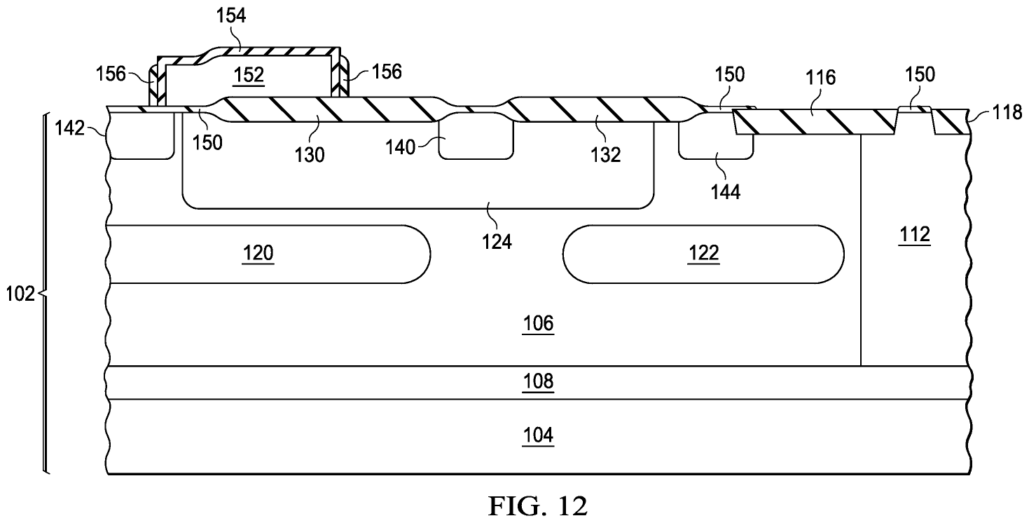

Referring to FIG. 12, the pad oxide layer 902 is removed. For example, the pad oxide layer 902 can be removed using an etch process, such as a wet etch. Then, the dielectric layer 150 is formed on the top major surface of the semiconductor substrate 102. In some examples, the dielectric layer 150 is formed by performing an oxidation process to oxide the semiconductor material (e.g., silicon) at the top major surface of the semiconductor substrate 102. Hence, in such examples, the dielectric layer 150 can be an oxide of the semiconductor material of the semiconductor substrate 102, such as silicon oxide. In other examples, the dielectric layer 150 can be deposited on or over the semiconductor substrate 102 using an appropriate deposition process, such as, for example, CVD, ALD, or the like.

A gate electrode 152 is then formed. A material of the gate electrode 152 is deposited on or over the dielectric layer 150 and second dielectric isolation regions 130, 132. The material of the gate electrode 152 can be or include, for example, polysilicon, metal, the like, or a combination thereof. The material of the gate electrode 152 can be deposited by any appropriate deposition process, such as CVD, physical vapor deposition (PVD), or the like. The material of the gate electrode 152 is then patterned into the gate electrode 152 using appropriate photolithography and etching processes.

A conformal oxide layer 154 is conformally formed on or over sidewall and upper surfaces of the gate electrode 152, and spacers 156 are formed on the conformal oxide layer 154 along sidewall surfaces of the gate electrode 152. In some examples, the conformal oxide layer 154 can be formed using an oxidation process to oxidize surfaces of the gate electrode 152. In some examples, the conformal oxide layer 154 can be formed by using an appropriate deposition process, such as CVD, ALD, or the like.

A material of spacers 156 is then deposited on or over the conformal oxide layer 154 and on exposed surfaces of the dielectric layer 150 and second dielectric isolation regions 130, 132. The material of the spacers 156 is different from the material of the conformal oxide layer 154, and hence, can be selectively etched relative to the conformal oxide layer 154. The material of the spacers 156 can be or include any appropriate dielectric material, such as a nitride, the like, or a combination thereof, and can be deposited using an appropriate deposition process, such as CVD, ALD, or the like. The material of the spacers 156 is then anisotropically etched, such as by a reactive ion etch (RIE), to remove substantially lateral portions and such that spacers 156 remain on the conformal oxide layer 154 along sidewalls of the gate electrode 152.

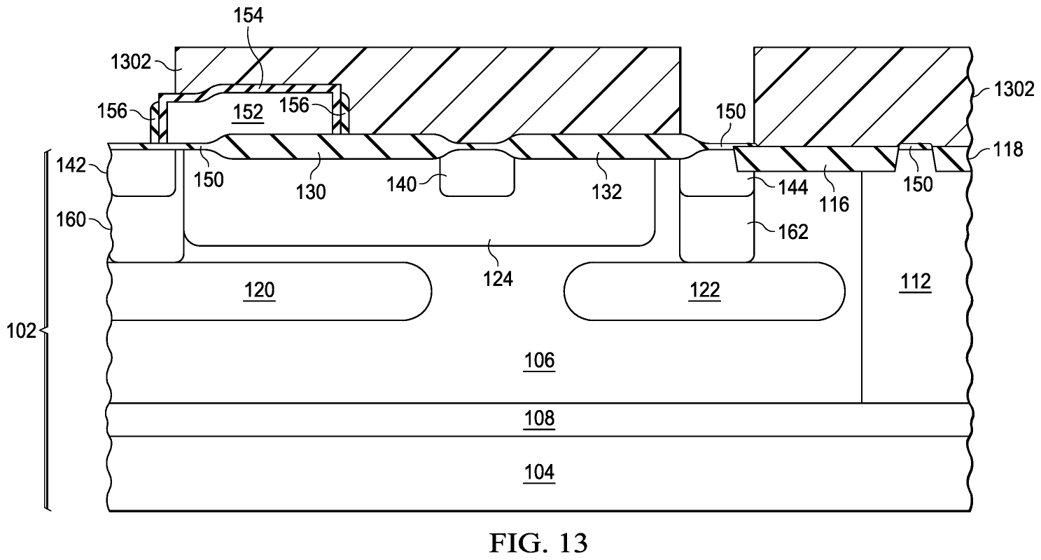

Referring to FIG. 13, a Dwell 160 and a mid-depth well 162 are formed in the semiconductor substrate 102. To form the Dwell 160 and the mid-depth well 162, a photoresist 1302 is deposited (e.g., by spin-on) on or over the semiconductor substrate 102 and patterned using photolithography. The photoresist 1302 is patterned to have respective openings corresponding to areas where the Dwell 160 and the mid-depth well 162 are to be formed. With the patterned photoresist 1302, an implant is performed to implant dopants into the semiconductor substrate 102 thereby forming the Dwell 160 and the mid-depth well 162. The dopant type and concentration of the Dwell 160 and the mid-depth well 162 are as described above. In some examples, the Dwell 160 and the mid-depth well 162 may be implanted to have a substantially uniform concentration in the illustrated Dwell 160 and the mid-depth well 162. In some examples, the implantation described with respect to FIG. 13 may include multiple implantations, such as including an implantation to a shallow depth and another implantation to a deeper depth.

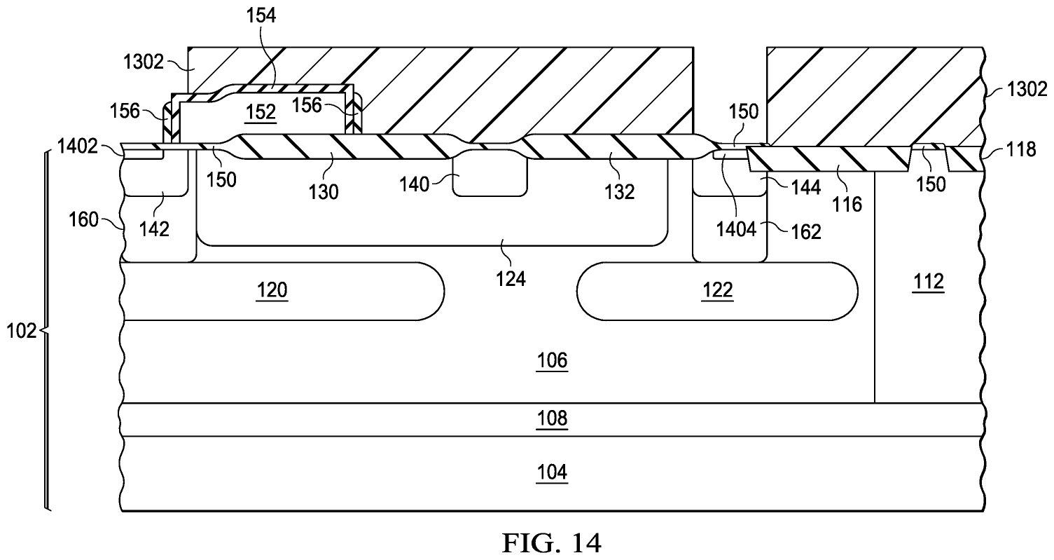

Referring to FIG. 14, intermediate regions 1402, 1404 are formed in the semiconductor substrate 102. With the patterned photoresist 1302, an implant is performed to implant dopants into the semiconductor substrate 102 thereby forming the intermediate regions 1402, 1404. The implant in FIG. 14 uses a dopant that has a same conductivity type as the source region 170 described above. The intermediate region 1402 is disposed in the second shallow well 142 extending from the top major surface of the semiconductor substrate 102 to a depth in the second shallow well 142 in the semiconductor substrate 102. The intermediate region 1404 is disposed in the second shallow well 144 extending from the top major surface of the semiconductor substrate 102 to a depth in the second shallow well 144 in the semiconductor substrate 102. In an n-channel LDMOS transistor, the intermediate regions 1402, 1404 can be n-doped with an n-type dopant at a concentration in a range from about 5×10¹⁹ cm⁻³ to about 1×10²¹ cm⁻³, e.g., heavily to very heavily doped. As described subsequently, the intermediate region 1402 is used to form the source region 170. After the implant, the photoresist 1302 is removed, such as by ashing.

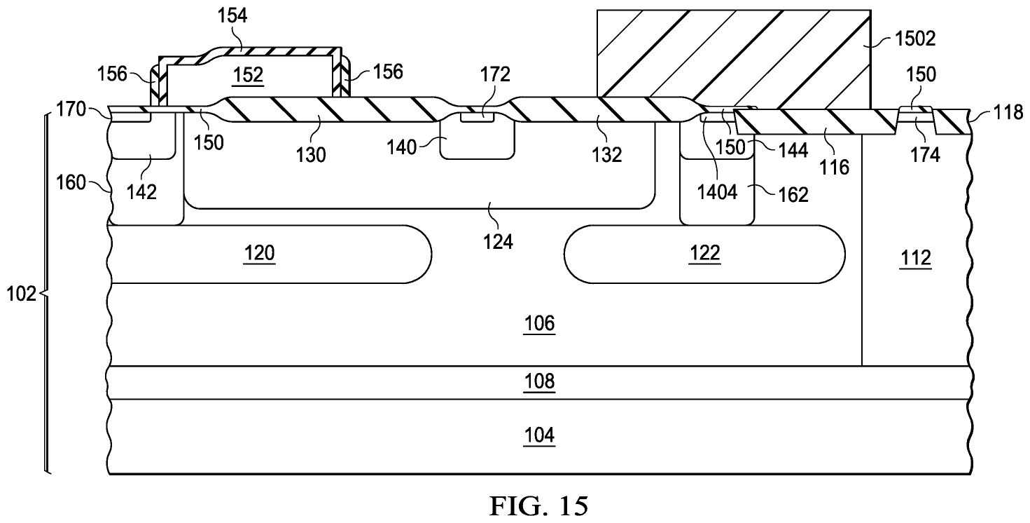

Referring to FIG. 15, a source region 170, a drain region 172, and a counter-isolation surface region 174 are formed in the semiconductor substrate 102. To form the source region 170, drain region 172, and counter-isolation surface region 174, a photoresist 1502 is deposited (e.g., by spin-on) on or over the semiconductor substrate 102 and patterned using photolithography. The photoresist 1502 is patterned to mask where the dopant isolation region 145 is being formed. With the patterned photoresist 1502, an implant is performed to implant dopants into the semiconductor substrate 102 thereby forming the source region 170, drain region 172, and counter-isolation surface region 174. The dopant type and concentration of the source region 170, drain region 172, and counter-isolation surface region 174 are as described above. It is noted that the intermediate region 1402 combines with dopants implanted in FIG. 15 to form the source region 170. After the implant, the photoresist 1502 is removed, such as by ashing.

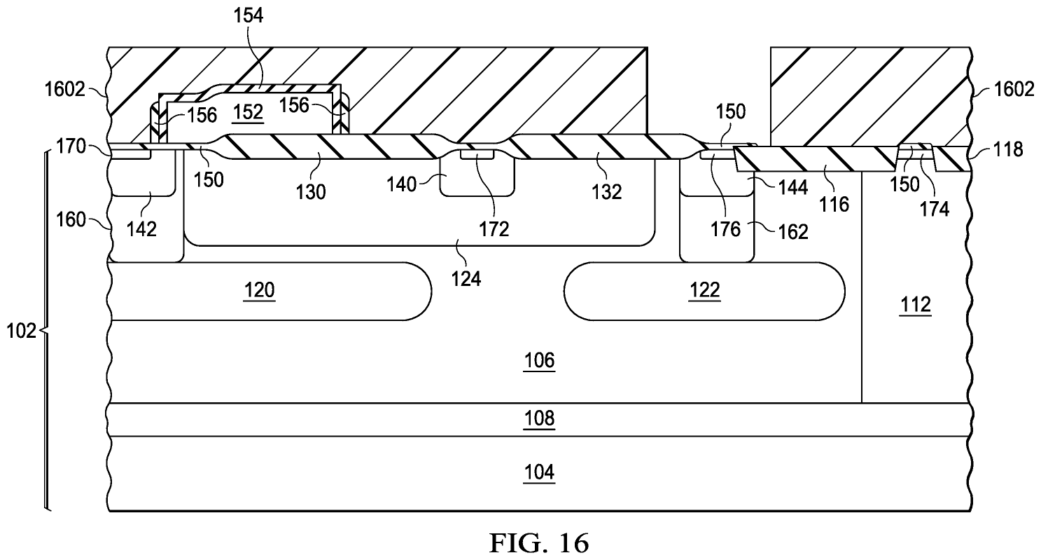

Referring to FIG. 16, an isolation surface region 176 is formed in the semiconductor substrate 102. To form the isolation surface region 176, a photoresist 1602 is deposited (e.g., by spin-on) on or over the semiconductor substrate 102 and patterned using photolithography. The photoresist 1602 is patterned to have an opening corresponding to an area where the isolation surface region 176 is to be formed. With the patterned photoresist 1602, an implant is performed to implant dopants into the semiconductor substrate 102 thereby forming the isolation surface region 176. The dopant type and concentration of the isolation surface region 176 are as described above. After the implant, the photoresist 1602 is removed, such as by ashing. It is noted that the isolation surface region 176, and thus, the implant of FIG. 16, may be omitted in some examples. An anneal process may be performed after the implantation of FIG. 16 to activate the dopants of the first shallow well 140, second shallow wells 142, 144, Dwell 160, the mid-depth well 162, source region 170, drain region 172, counter-isolation surface region 174, and isolation surface region 176.

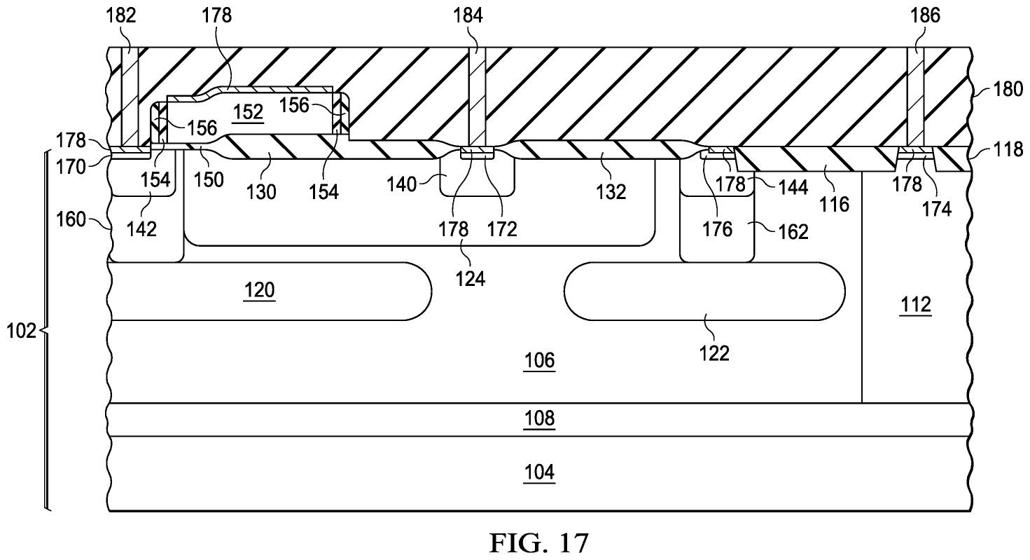

Referring to FIG. 17, semiconductor-metal compound regions 178 are formed. To form the semiconductor-metal compound regions 178, exposed portions of the dielectric layer 150 and the conformal oxide layer 154 are removed. For example, the dielectric layer 150 and the conformal oxide layer 154 can be removed using an etch process. The removal of portions of the dielectric layer 150 and the conformal oxide layer 154 may also cause some loss from exposed upper portions of the second dielectric isolation regions 130, 132. A metal of the semiconductor-metal compound regions 178 is deposited. The metal may be deposited using any appropriate deposition process, such as PVD, CVD, the like, or a combination thereof. An anneal process is implemented to react metal to underlying semiconductor material (e.g., silicon (Si)) to form the semiconductor-metal compound regions 178. A respective semiconductor-metal compound region 178 is therefore formed on the source region 170, on the drain region 172, on the counter-isolation surface region 174, on the isolation surface region 176, and on the gate electrode 152. It is noted that, in some examples, a semiconductor-metal compound region 178 may not be formed on the isolation surface region 176. Unreacted metal is then removed, for example, using an etch process selective to the metal.

A dielectric layer 180 is formed, and a source contact 182, drain contact 184, and counter-isolation contact 186 are formed through the dielectric layer 180. The dielectric layer 180 can include one or multiple dielectric layers formed of any appropriate dielectric material and deposited by any appropriate deposition process, such as CVD, PVD, or the like. Openings are then formed through the dielectric layer 180 using photolithography and etching processes. Respective openings expose respective semiconductor-metal compound regions 178 that are disposed on the source region 170, on the drain region 172, and on the counter-isolation surface region 174. A barrier and/or adhesion layer may then be conformally deposited, such as by CVD, ALD, or the like, in the openings, and a fill metal can be deposited, such as by CVD, PVD, or the like, on the barrier and/or adhesion layer. Any barrier and/or adhesion layer and fill material on the top surface of the dielectric layer 180 may be removed by CMP, for example. Hence, each of the source contact 182, drain contact 184, and counter-isolation contact 186 can include a barrier and/or adhesion layer and a fill metal. After the source contact 182, drain contact 184, and counter-isolation contact 186 are formed, no contact is disposed through the dielectric layer 180 to the dopant isolation region 145 (e.g., to the isolation surface region 176, second shallow well 144, and/or mid-depth well 162).

Although various examples have been described in detail, it should be understood that various changes, substitutions, and alterations can be made therein without departing from the scope defined by the appended claims.

What is claimed is:

1. A semiconductor device comprising:
a drift well disposed in a semiconductor substrate, the drift well being doped with a first dopant conductivity type;
a drain region disposed in the semiconductor substrate, the drain region being disposed within the drift well, the drain region being doped with the first dopant conductivity type;
a first dopant isolation region disposed in the semiconductor substrate and circumscribing the drain region, the first dopant isolation region being doped with a second dopant conductivity type opposite from the first dopant conductivity type, the first dopant isolation region being an electrically floating node; and
a second dopant isolation region disposed in the semiconductor substrate and circumscribing the first dopant isolation region, the second dopant isolation region being doped with the first dopant conductivity type.

2. The semiconductor device of claim 1, wherein:
the drift well is a first n-doped well;
the drain region is an n-doped region;
the first dopant isolation region includes a p-doped well; and
the second dopant isolation region includes a second n-doped well.

3. The semiconductor device of claim 1, wherein the first dopant isolation region forms a common anode of a first diode between the first dopant isolation region and the drain region and of a second diode between the first dopant isolation region and the second dopant isolation region.

4. The semiconductor device of claim 1, further comprising a source region disposed in the semiconductor substrate, a source-drain distance being from a center of the source region to a center of the drain region, wherein a distance between the first dopant isolation region and the center of the drain region is no greater than 75% of the source-drain distance.

5. The semiconductor device of claim 1, further comprising a source region disposed in the semiconductor substrate, a source-drain distance being from a center of the source region to a center of the drain region, wherein a distance between the first dopant isolation region and the second dopant isolation region is no greater than 75% of the source-drain distance.

6. The semiconductor device of claim 1, further comprising a source region disposed in the semiconductor substrate, a source-drain distance being from a center of the source region to a center of the drain region, wherein a distance between the second dopant isolation region and the center of the drain region plus a width of the second dopant isolation region is no greater than 175% of the source-drain distance.

7. The semiconductor device of claim 1, wherein:
the first dopant isolation region comprises:
a first well doped with the second dopant conductivity type; and
a second well disposed in the first well, the second well being doped with the second dopant conductivity type, a concentration of a dopant of the second dopant conductivity type in the second well being greater than a concentration of a dopant of the second dopant conductivity type in the first well; and
the second dopant isolation region comprises:
a third well doped with the first dopant conductivity type; and
an isolation surface region disposed in the third well, the isolation surface region being doped with the first dopant conductivity type, a concentration of a dopant of the first dopant conductivity type in the isolation surface region being greater than a concentration of a dopant of the first dopant conductivity type in the third well.

8. The semiconductor device of claim 1, further comprising:
a double diffusion well disposed in the semiconductor substrate, the double diffusion well being doped with the second dopant conductivity type;
a source region disposed in the double diffusion well, the source region being doped with the first dopant conductivity type; and
a gate electrode disposed on or over the semiconductor substrate, the gate electrode being disposed laterally between the source region and the drain region.

9. The semiconductor device of claim 1, further comprising a buried layer having the first dopant conductivity type, wherein the second dopant isolation region extends from a top surface of the semiconductor substrate to the buried layer.

10. The semiconductor device of claim 1, further comprising a buried layer having the second dopant conductivity type, wherein the first dopant isolation region extends from a top surface of the semiconductor substrate to the buried layer.

11. The semiconductor device of claim 10, wherein the buried layer is located within a lightly doped epitaxial layer having the second dopant conductivity type, and the buried layer extends from the first dopant isolation region toward the second dopant isolation region, a portion of the lightly doped epitaxial layer located directly laterally between the buried layer and the second dopant isolation region.

12. The semiconductor device of claim 1, wherein the first dopant conductivity type is N-type and the second dopant conductivity type is P-type.

13. A method of forming a semiconductor device, the method comprising:
forming a drift well in a semiconductor substrate, the drift well being doped with a first dopant conductivity type;
forming a drain region in the drift well, the drain region being doped with the first dopant conductivity type, a concentration of a dopant of the first dopant conductivity type in the drain region being greater than a concentration of a dopant of the first dopant conductivity type in the drift well;
forming a first dopant isolation region in the semiconductor substrate, the first dopant isolation region laterally surrounding the drain region and being doped with a second dopant conductivity type opposite from the first dopant conductivity type;
forming a second dopant isolation region in the semiconductor substrate, the first dopant isolation region laterally surrounding the drain region and being disposed laterally between the drift well and the second dopant isolation region, the second dopant isolation region being doped with the first dopant conductivity type; and
forming a dielectric layer on or over the semiconductor substrate; and
wherein the first dopant isolation region is configured to be unconnected to any constant or varying voltage source or ground reference during operation of the semiconductor device.

14. The method of claim 13, wherein:
the drift well is a first n-doped well;
the drain region is an n-doped region;
the first dopant isolation region includes a p-doped well; and
the second dopant isolation region includes a second n-doped well.

15. The method of claim 13, wherein no direct conductive contact is made to the first dopant isolation region.

16. The method of claim 13, further comprising forming a source region in the semiconductor substrate, a source-drain distance being from a center of the source region to a center of the drain region, wherein a distance between the second dopant isolation region and the center of the drain region plus a width of the second dopant isolation region is no greater than 175% of the source-drain distance.

17. An integrated circuit comprising:
an n-doped drift well disposed in a semiconductor substrate;
an n-doped drain region disposed in the n-doped drift well, a concentration of an n-type dopant in the n-doped drain region being greater than a concentration of an n-type dopant in the n-doped drift well;
a p-doped well region disposed in the semiconductor substrate and laterally surrounding the n-doped drain region, the p-doped well region being an electrically floating node; and
an n-doped isolation region disposed in the semiconductor substrate, the p-doped well region being disposed laterally between the n-doped drift well and the n-doped isolation region.

18. The integrated circuit of claim 17, wherein:
the p-doped well region comprises:
a first p-doped well disposed in the semiconductor substrate; and
a second p-doped well disposed in the semiconductor substrate, the second p-doped well being disposed in the first p-doped well, a concentration of a p-type dopant in the second p-doped well being greater than a concentration of a p-type dopant in the first p-doped well; and
the n-doped isolation region comprises:
an n-doped well disposed in the semiconductor substrate; and
an n-doped isolation surface region disposed in the semiconductor substrate, the n-doped isolation surface region being disposed in the n-doped well, a concentration of an n-type dopant in the n-doped isolation surface region being greater than a concentration of an n-type dopant in the n-doped well.

19. The integrated circuit of claim 17, further comprising:
a p-doped double diffusion well disposed in the semiconductor substrate;
an n-doped source region disposed in the semiconductor substrate, the n-doped source region being disposed in the p-doped double diffusion well; and
a gate electrode disposed on or over the semiconductor substrate, the gate electrode being disposed laterally between the n-doped source region and the n-doped drain region.

20. The integrated circuit of claim 17, further comprising an n-doped source region disposed in the semiconductor substrate, a source-drain distance being from a center of the n-doped source region to a center of the n-doped drain region, wherein a distance between the n-doped isolation region and the center of the n-doped drain region plus a width of the n-doped isolation region is no greater than 175% of the source-drain distance.
